(19) United States
(12) Patent Application Publication
(10) Pub. No.: US 2024/0203982 A1
(43) Pub. Date: Jun. 20, 2024

(54) DECOUPLING CAPACITOR INSIDE BACKSIDE POWER DISTRIBUTION NETWORK POWERVIA TRENCH

(71) Applicant: INTERNATIONAL BUSINESS MACHINES CORPORATION, ARMONK, NY (US)

(72) Inventors: Reinaldo Vega, Mahopac, NY (US); Nicholas Anthony Lanzillo, Wynantskill, NY (US); David Wolpert, Poughkeepsie, NY (US); Takashi Ando, Eastchester, NY (US)

(21) Appl. No.: 18/069,213

(22) Filed: Dec. 20, 2022

(51) Int. Cl. H01L 27/06; H01L 23/522; H01L 23/528; H01L 29/66

(52) U.S. Cl. CPC H01L 27/0629; H01L 23/5223; H01L 23/5226; H01L 23/5286; H01L 29/66181

(57) ABSTRACT

A logic cell includes a first trench capacitor disposed between and connecting a topside metal layer to a backside metal layer. The first trench capacitor includes an outer plate, connected to a first power rail on the backside metal layer, an inner plate, connected to a second power rail on backside metal layer, and an insulating layer separating the inner plate from the outer plate.

### BACKGROUND

The present disclosure generally relates to structures and methods for increasing decoupling capacitance density in a semiconductor device, and more particularly, to a decoupling capacitor inside a backside power distribution network (BSPDN) powervia trench.

Fill cells are used predominantly in DD1 layouts as backup active regions for DD2 re-design. These are inactive cells within DD1 layouts and so are configured to achieve decoupling capacitance. Fill cell capacitance comes primarily from gate to source/drain contact area (PC-CA) capacitance and therefore does not achieve very high capacitance density per cell. Such conventional fill cell capacitance does not achieve very high capacitance density per cell, typically about 20 fF/um², normalized to fill cell area.

Accordingly, there is a need to provide a fill cell structure that can increase the total decoupling capacitance density within a fill cell.

### SUMMARY

According to one embodiment, a semiconductor device comprises a structure to achieve a substantial decoupling capacitance density within a fill cell by providing at least one parallel plate capacitor inside at least one trench between a topside metal layer and a backside metal layer.

In one embodiment that can be combined with the preceding embodiment, a logic cell includes a first trench capacitor disposed between and connecting a topside metal layer to a backside metal layer. The first trench capacitor includes an outer plate, connected to a first power rail on the backside metal layer, and an inner plate, connected to a second power rail on backside metal layer. An insulating layer separates the inner plate from the outer plate. The trench capacitor can be filled into a first trench of the fill cell. The trench capacitor can greatly increase the overall capacitance of a fill call beyond that of typical PC-CA capacitance.

In one embodiment that can be combined with the preceding embodiment, the trench capacitor is a parallel plate capacitor.

In one embodiment that can be combined with the preceding embodiment, a metal conductor connects a first frontside via bar with the second power rail on the backside metal layer. The metal conductor can be disposed in a second trench in the fill cell.

In one embodiment that can be combined with the preceding embodiment, the outer plate is directly electrically connected to the first power rail, the inner plate is directly electrically connected to the first frontside via bar on the topside metal layer, and the first frontside via bar is connected to a metal conductor directly electrically connected to the second power rail.

In one embodiment that can be combined with the preceding embodiment, the insulating layer can include multiple alternating layers of a ferroelectric material and a dielectric material stacked on top each other. Such an alternating layering of the insulating layer can provide an improved charge response of the trench capacitor.

In one embodiment that can be combined with the preceding embodiment, a logic cell includes a first trench capacitor disposed between and connecting a topside metal layer to a backside metal layer. The first trench capacitor includes an outer plate, connected to a first power rail on the backside metal layer, an inner plate, connected to a second power rail on backside metal layer, and an insulating layer separating the inner plate from the outer plate. A metal conductor electrically connects a second frontside via bar with the second power rail on the backside metal layer. The trench capacitor can greatly increase the overall capacitance of a fill call beyond that of typical PC-CA capacitance.

According to another embodiment, a logic cell includes a first trench capacitor and a second trench capacitor, each disposed between and connecting a topside metal layer to a backside metal layer. The first trench capacitor a first outer plate, directly electrically connected to a first power rail on the backside metal layer, a first inner plate, connected to a second power rail on backside metal layer, and a first insulating layer separating the inner plate from the outer plate. The second trench capacitor includes a second outer plate, directly electrically connected to the second power rail on the backside metal layer. There is a second inner plate, connected to the first power rail on backside metal layer, and a second insulating layer separating the inner plate from the outer plate. The first and second trench capacitors can greatly increase the overall capacitance of a fill call beyond that of typical PC-CA capacitance.

By virtue of the concepts discussed herein, improved process and resulting structures provide a decoupling capacitor inside a BSPDN powervia trench. Such a system increases the capacitance density in a fill cell beyond that provided by conventional PC-CA capacitance, thus reducing noise in a semiconductor device.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1A depicts a cross-sectional view taken along line I-I of FIG. 1B of a fill cell having a trench capacitor according to an illustrative embodiment.

FIG. 1B depicts a top-down view of the fill cell of FIG. 1A.

FIG. 2A depicts a cross-sectional view taken along line II-II of FIG. 2B of a fill cell having a trench capacitor according to an illustrative embodiment.

FIG. 2B depicts a top-down view of the fill cell of FIG. 2A.

FIG. 3A depicts a cross-sectional view taken along line III-III of FIG. 3B of a fill cell having a trench capacitor according to an illustrative embodiment.

FIG. 3B depicts a top-down view of the fill cell of FIG. 3A.

FIG. 4A depicts a cross-sectional view taken along line IV-IV of FIG. 4B of a fill cell having a trench capacitor according to an illustrative embodiment.

FIG. 4B depicts a top-down view of the fill cell of FIG. 4A.

FIG. 5A depicts a cross-sectional view taken along line V-V of FIG. 5B of a fill cell having a trench capacitor according to an illustrative embodiment.

FIG. 5B depicts a top-down view of the fill cell of FIG. 5A.

FIGS. 6A through 6H illustrate exemplary processing steps for making the fill cell of FIG. 1A.

FIGS. 7A through 7I illustrate exemplary processing steps for making the fill cell of FIG. 2A.

### DETAILED DESCRIPTION

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In some embodiments, etching mask layer(s) may be provided, and the layers that are not protected thereby are removed. For example, as is understood in the art, a mask layer, sometimes referred to as a photomask, may be provided by forming a layer of photoresist material on another layer, exposing the photoresist material to a pattern of light, and developing the exposed photoresist material. An etching process, such as a reactive ion etch (RIE), may be used to form patterns (e.g., openings) by removing portions of another layer. After etching, the mask layer may be removed using a conventional plasma ashing or stripping process. Accordingly, the pattern of the mask layer facilitates the removal of another layer, such as an amorphous SiO2 layer and/or a conductive oxide diffusion barrier, for example, in areas where the mask layer has not been deposited.

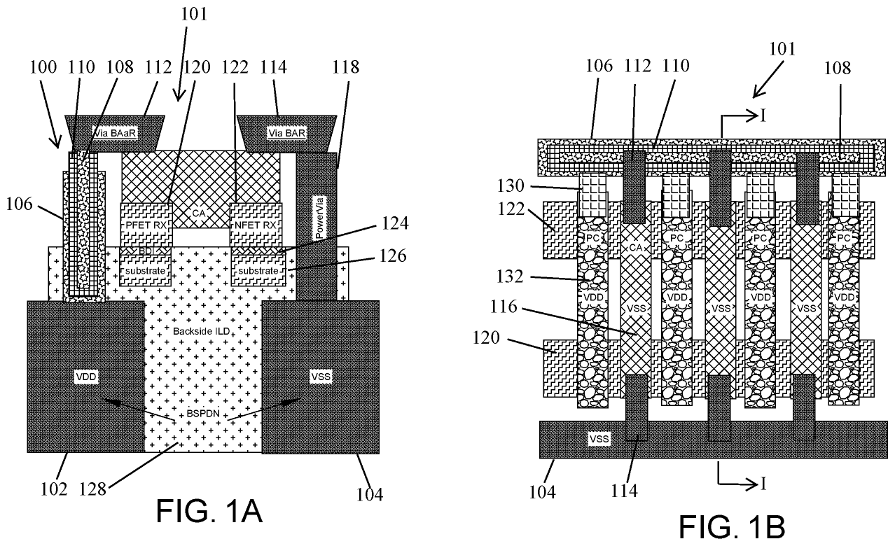

Referring to FIGS. 1A and 1B, a trench capacitor 100 (also referred to as capacitor 100) can have both electrodes connected to the backside metallization of a fill cell 101 (also referred to as a logic cell). The backside metallization can include a drain line (VDD line 102) and a source line (VSS line 104). An outer plate 106 of the capacitor 100 can electrically connect to VDD line 102, while an inner plate 108 can electrically connect to VSS line 104 through front side via bars 112, 114, that are electrically connected through a source drain contact 116, and a powervia 118.

The capacitor 100 can include an insulating layer 110 that may be a dielectric material layer or a combination of ferroelectric material layers and dielectric material layers. For example, the insulating layer 110 may include multiple alternating layers of ferroelectric material and dielectric material stacked on top each other. In such cases, the dielectric material layers may be made from the same or different dielectric materials. In another embodiment, the insulating layer 110 may include a single ferroelectric layer sandwiched between multiple dielectric material layers. Thus, the capacitor 100 may be a metal insulator metal (MIM) capacitor or a metal ferroelectric insulator metal (MFIM) capacitor, for example. In some embodiments, the MFIM capacitor may provide an improved charge response as compared to the MIM capacitor.

The fill cell 101 may further include conventional elements, such as a P-type field effect transistor (PFET 120), an N-type field effect transistor (NFET 122), bottom dielectric isolation layer 124, substrate 126, and backside interlayer dielectric fill 128. A gate contact 130) can connect the transistors (PFET 120 and NFET 122) to the upper metal level via a gate line 132).

In the structure of FIGS. 1A and 1B, the PC-CA capacitance is in parallel with the capacitance of the trench capacitor 100. For example, the capacitance between the gate line 132 and the source drain contact 116 is parallel to the capacitance of the trench capacitor 100. Further the NFET 122 is biased to inversion, providing additional gate-to-channel capacitance in parallel with the PC-CA and the capacitance of the trench capacitor 100.

In some embodiments, while the trench capacitor 100 is shown as a continuous powervia capacitor, such a capacitor may be formed as a plurality of individual capacitors within separate powervias.

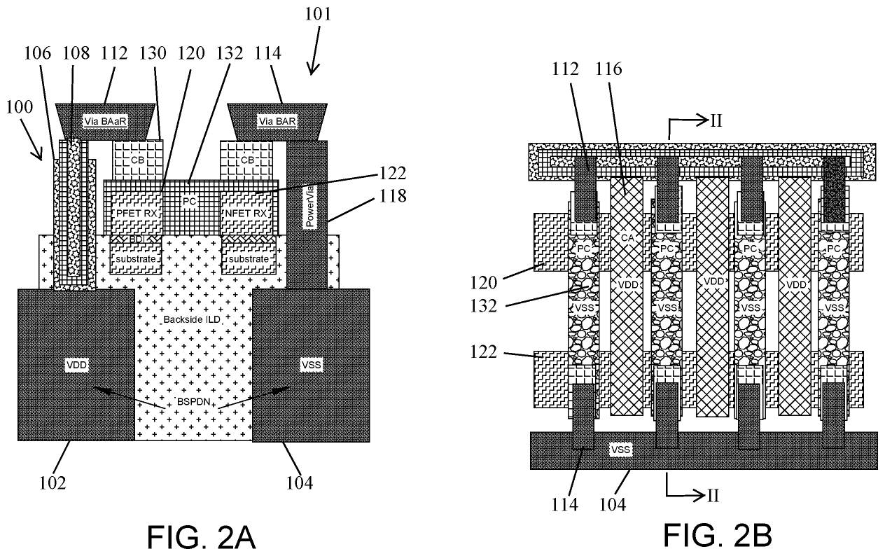

Referring to FIGS. 2A and 2B, the base structures may be similar to those described in FIGS. 1A and 1B, however the electrical connections and the resulting overall capacitance may differ as described in greater detail below.

In this embodiment, the inner plate 108 is electrically connected to the opposing rail through PC 132, while the outer plate 106 is connected to the VDD line 102 and to source drain contact 116. Thus, the overall result is the similar to that of FIGS. 1A and 1B in that the plates of the capacitor 100 are connected to the backside metallization (the VDD line 102 and the VSS line 104), albeit through different contacts through the transistors.

In the embodiment of FIGS. 2A and 2B, the PC-CA capacitance (for example, the capacitance between the gate line 132 and the source drain contact 116) is in parallel with the capacitance of the trench capacitor 100 and the PFET 120 is biased to inversion, where additional gate-to-channel capacitance is in parallel with PC-CA and trench capacitor 100 capacitances.

In some embodiments, while the trench capacitor 100 is shown as a continuous powervia capacitor, such a capacitor may be formed as a plurality of individual capacitors within separate powervias.

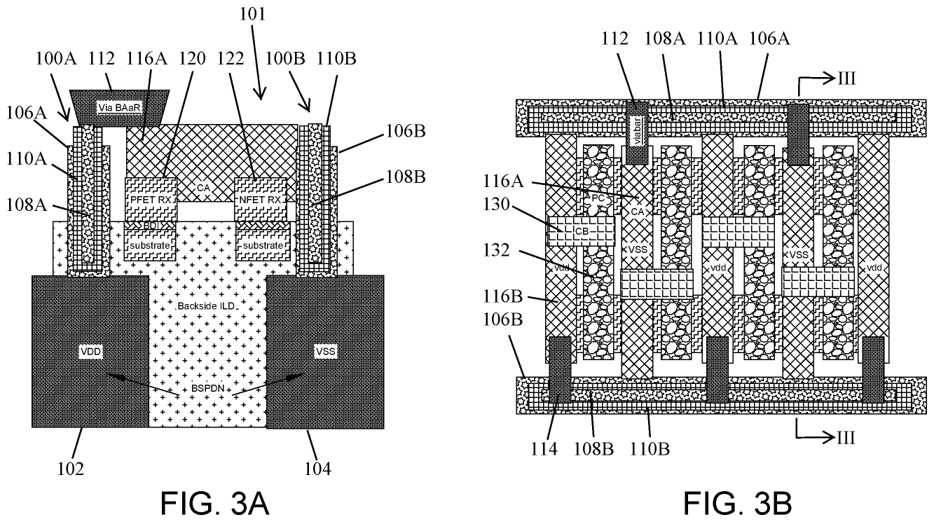

Referring to FIGS. 3A and 3B, the base structures may be similar to those described in FIGS. 1A and 1B, however the electrical connections and the resulting overall capacitance may differ as described in greater detail below.

In some embodiments, the powervia 118, as shown in FIGS. 1A through 2B may be replaced by a second trench capacitor 100B (also referred to second capacitor) that is used in addition to a first trench capacitor 100A (also referred to as first capacitor). Each of the first and second capacitors 100A, 100B may be MIM or MFIM capacitors, for example, disposed within the powervia trench region of the fill cell 101.

In the embodiment of FIGS. 3A and 3B, the first inner plate 108A is electrically connected to the second outer plate 106B through the source drain contact 116A and via bar 112 (e.g., busbar) as a local interconnect. This connection is made for every other source drain contact 116A, where the remaining, alternate ones of the source drain contact 116B electrically connect the second inner plate 108B to the first outer plate 106A. A gate contact 130 connects the gate line 132 to two adjacent source drain contacts 116A, 116B as seen in FIG. 3B. The first and second inner plates 108A, 108B can be separated by an insulating layer 110A, 110B from the respective first and second outer plates 106A, 106B.

In this embodiment, PC-CA capacitance (for example, capacitance between the gate line 132 and the source drain contact 116) is in parallel with the capacitance of the first and second trench capacitors 100A, 100B and half of both the NFET 122 and the PFET 120 are biased to inversion, where additional gate-to-channel capacitance is in parallel with the PC-CA capacitance and the capacitance of the first and second trench capacitors 100A, 100B.

In some embodiments, while the first and second trench capacitors 100A, 100B are shown as continuous powervia capacitors, such capacitors may be formed as a plurality of individual capacitors within separate powervias.

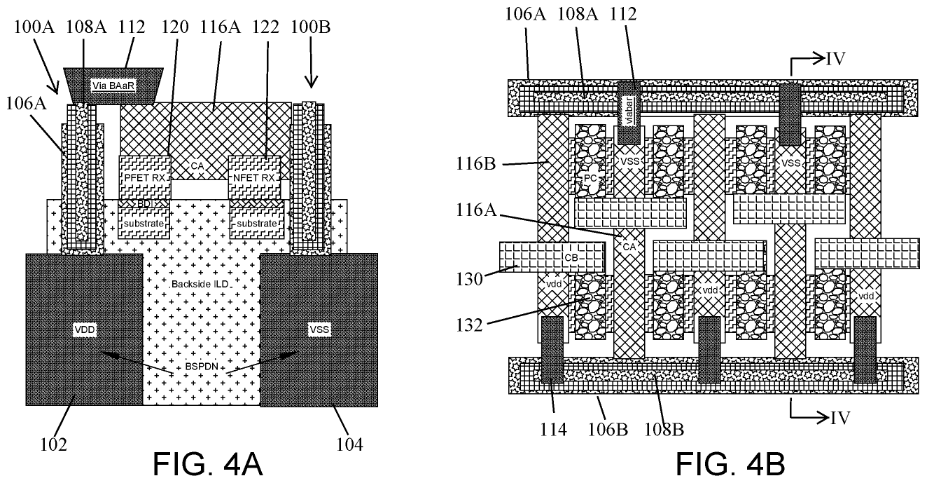

Referring to FIGS. 4A and 4B, the base structures may be similar to those described in FIGS. 1A and 1B, however the electrical connections and the resulting overall capacitance may differ as described in greater detail below. In some embodiments, the powervia 118, as shown in FIGS. 1A through 2B may be replaced by a second trench capacitor 100B (also referred to second capacitor) that is used in addition to a first trench capacitor 100A (also referred to as first capacitor). Each of the first and second capacitors 100A, 100B may be MIM or MFIM capacitors, for example, disposed within the powervia trench region of the fill cell 101.

Similar to the embodiment of FIGS. 3A and 3B, the first inner plate 108A is connected to the second outer plate 106B through the source drain contact 116A as local interconnect. This connection is made for every other source drain contact 116A, where the remaining, alternate ones of the source drain contact 116B electrically connect the second inner plate 108B to the first outer plate 106A. In other words, a first set of source drain contacts include the source drain contact 116A, while a second set of source drain contacts include the source drain contact 116B, where the first and second sets of source drain contacts are disposed in an alternating arrangement in the fill cell.

In the embodiment of FIGS. 4A and 4B, the gate lines 132 are cut between the NFET 122 and the PFET 120. The source drain contact 116A is connected to adjacent upper ones of the cut gate lines 132 on each side thereof, and the source drain contact 116B is connected to adjacent lower ones of the cut gate lines 132 on each side thereof, as shown in FIG. 4B.

With the cut gate lines 132, there are separate N and P connections. All NFET 122 and PFET 120 are biased to inversion, where additional gate-to-channel capacitance is in parallel with the PC-CA and the first and second trench capacitors 100A, 100B capacitances.

In some embodiments, while the trench capacitors 100A, 100B are shown as continuous powervia capacitors, such capacitors may be formed as a plurality of individual capacitors within separate powervias.

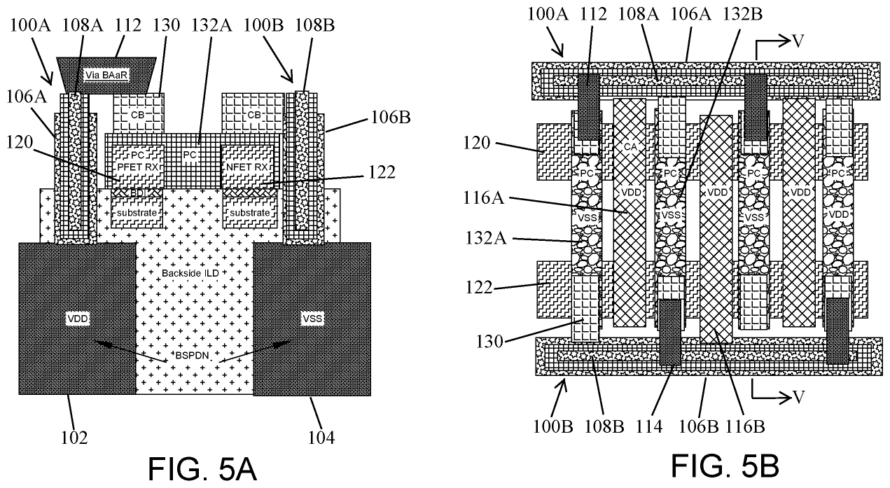

Referring to FIGS. 5A and 5B, the base structures may be similar to those described in FIGS. 1A and 1B, however the electrical connections and the resulting overall capacitance may differ as described in greater detail below. In some embodiments, the powervia 118, as shown in FIGS. 1A through 2B may be replaced by a second trench capacitor 100B (also referred to second capacitor) that is used in addition to a first trench capacitor 100A (also referred to as first capacitor). Each of the first and second capacitors 100A, 100B may be MIM or MFIM capacitors, for example, disposed within the powervia trench region of the fill cell 101.

The first inner plate 108A is connected to the second outer plate 106B through the gate line 132A. This connection is made for every other gate line 132A, where the remaining, alternate ones of the gate line 132B electrically connect the first outer plate 106A to the second inner plate 108B.

The first inner plate 108A is electrically connected to the transistors (NFET 122 and PFET 120) through the source drain contact 116A and via bar 112 (e.g., busbar) as a local interconnect. This connection is made for every other source drain contact 116A, where the remaining, alternate ones of the source drain contact 116B electrically connect the second inner plate 108B to the transistors (NFET 122 and PFET 120).

In this embodiment, half of the NFET 122 and PFET 120 are biased to inversion, where additional gate-to-channel capacitance is in parallel with the PC-CA and the first and second trench capacitor 100A, 100B capacitances.

In some embodiments, while the first and second trench capacitors 100A, 100B are shown as a continuous powervia capacitor, such capacitors may be formed as a plurality of individual capacitors within separate powervias.

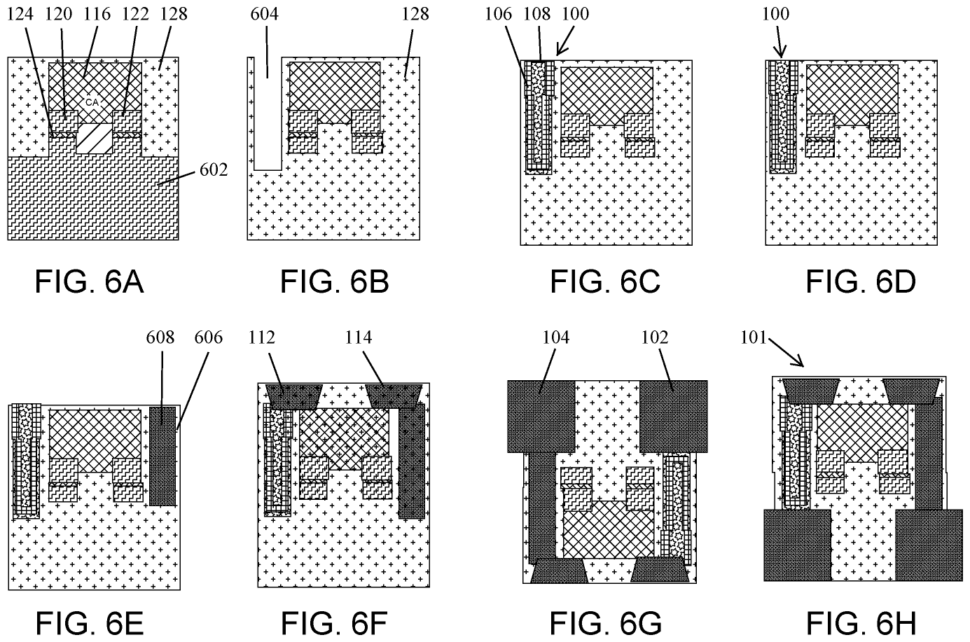

FIGS. 6A through 6H illustrates an exemplary processing steps for making the fill cell of FIG. 1A. It should be understood that the steps may not be performed in the sequence of the Figures, but may be changed to achieve the same end result. For example, from FIG. 6A to FIG. 6B, the substrate 602 is removed and replaced with interlayer dielectric fill 128. As illustrated, this would require multiple wafer flips, where, instead, the substrate 602 may be kept in place until the backside metal processing occurs in FIG. 6G. Other similar changes may be made without departing from the scope of the present disclosure.

In FIG. 6A, front end of line processing is performed, including the PFET 120 and the NFET 122, along with source drain contact 116. A frontside pattern is performed along with etching of a first via trench 604 as shown in FIG. 6B. In FIG. 6C, MIM or MFIM capacitor fill is performed, including recessing the outer plate 106 thereof. In FIG. 6D, the outer electrode is recessed, interlayer dielectric fill is performed, followed by chemical-mechanical planarization (CMP). In FIG. 6E, a second via trench 606 is etched and metal fill 608 is added, followed by CMP. In FIG. 6F, vias bars 112, 114 can be formed and interlayer dielectric deposited. In FIG. 6G, backside metal processing is performed, including placement of the VDD line 102 and the VSS line 104 to produce the final cell 101 of FIG. 6H.

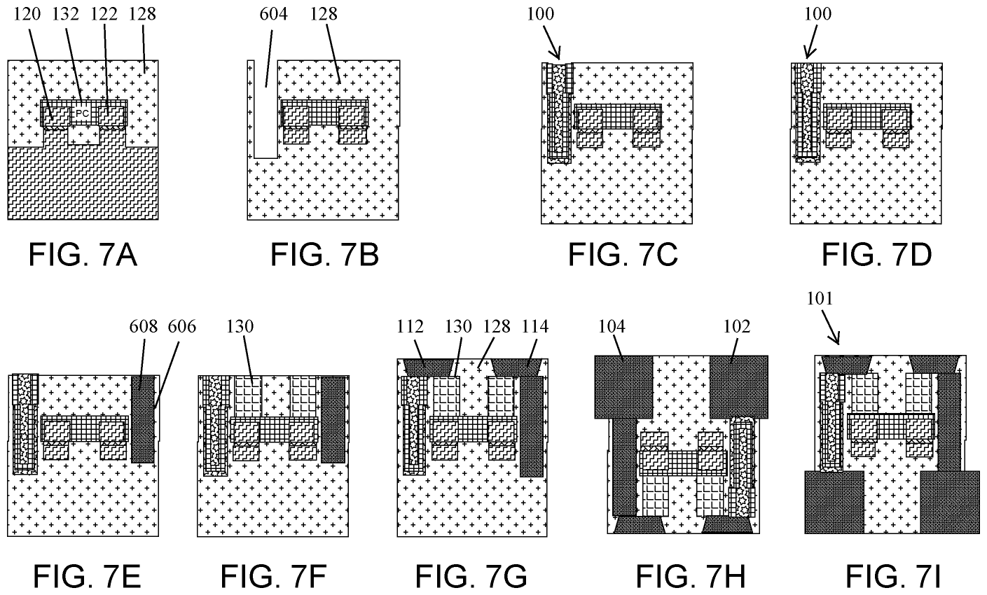

FIGS. 7A through 7I illustrates an exemplary processing steps for making the fill cell of FIG. 2A. It should be understood that the steps may not be performed in the sequence of the Figures, but may be changed to achieve the same end result. For example, from FIG. 7A to FIG. 7B, the substrate 602 is removed and replaced with interlayer dielectric fill 128. As illustrated, this would require multiple wafer flips, where, instead, the substrate 602 may be kept in place until the backside metal processing occurs in FIG. 7H. Other similar changes may be made without departing from the scope of the present disclosure.

In FIG. 7A, front end of line processing is performed, including the PFET 120 and the NFET 122, along with PC 132. A frontside patterning is performed along with etching of a first via trench 604, as shown in FIG. 7B. In FIG. 7C, MIM or MFIM capacitor fill is performed, including recessing the outer plate 106 thereof. In FIG. 7D, the outer electrode is recessed, interlayer dielectric fill is performed, followed by chemical-mechanical planarization (CMP). In FIG. 7E, a second via trench 606 is etched and metal fill 608 is added, followed by CMP. In FIG. 7F, the source drain contact 130 is formed on the gate line 132, adjacent the capacitor 100 and the metal fill 608. In FIG. 7G, vias bars 112, 114 can be formed and interlayer dielectric fill 128 deposited. In FIG. 7H, backside metal processing is performed, including placement of the VDD line 102 and the VSS line 104 to produce the final fill cell 101 of FIG. 7I.

The steps illustrates in FIGS. 6A through 7I may be carried out by known fabrication processes. The substrate 602 can be made of any suitable substrate material, such as, for example, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs) and quaternary (four elements, e.g., aluminum gallium indium phosphide (AlInGaP)) alloys.

In some embodiments, the nanosheet stacks (not shown) can initially include one or more semiconductor layers alternating with one or more sacrificial layers, also referred to as SiGe layers. Such nanosheet stacks may be used for patterning the NFET 122 and the PFET 120 on the substrate to provide the starting product shown in FIGS. 6A and 7A.

In an exemplary fill cell 101, a single trench capacitor, as shown in FIGS. 1A through 2B, can provide about 60-140 fF/um² which is about 3 to about 7 times the capacitance of the PC-CA capacitance (about 20 fF/um²). A dual trench capacitor, as shown in FIGS. 3A through 5B, can provide about 96-244 fF/um² which is about 5 to 12 times the capacitance of the PC-CA capacitance.

In one aspect, the method and structures as described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

The components, steps, features, objects, benefits and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

What is claimed is:

1. A logic cell comprising:
a first trench capacitor disposed between and connecting a topside metal layer to a backside metal layer, wherein the first trench capacitor comprises:
an outer plate connected to a first power rail on the backside metal layer;
an inner plate connected to a second power rail on backside metal layer; and
an insulating layer separating the inner plate from the outer plate.

2. The logic cell of claim 1, wherein the first trench capacitor is a parallel plate capacitor.

3. The logic cell of claim 1, further comprising a metal conductor connecting a first frontside via bar with the second power rail on the backside metal layer.

4. The logic cell of claim 3, wherein:
the outer plate is directly electrically connected to the first power rail;
the inner plate is directly electrically connected to the first frontside via bar on the topside metal layer; and
the first frontside via bar is connected to a metal conductor directly electrically connected to the second power rail.

5. The logic cell of claim 4, further comprising:
a source drain contact electrically connecting the first frontside via bar to a second frontside via bar, the second frontside via bar electrically connected to the second power rail; and
a gate contact electrically connecting the outer plate of the first trench capacitor to a gate line of the logic cell.

6. The logic cell of claim 4, further comprising:
a gate line electrically connecting the first frontside via bar to a second frontside via bar, the second frontside via bar electrically connected to the second power rail; and
a source drain contact of the logic cell electrically connected to the outer plate of the first trench capacitor.

7. The logic cell of claim 1, wherein the insulating layer includes multiple alternating layers of a ferroelectric material and a dielectric material stacked on top each other.

8. The logic cell of claim 1, wherein the first power rail is a VSS line and the second power rail is a VDD line.

9. The logic cell of claim 1, further comprising:
a second trench capacitor disposed between and connecting the topside metal layer to the backside metal layer, wherein the second trench capacitor comprises:
a second outer plate connected to a second power rail on the backside metal layer;
a second inner plate connected to the first power rail on backside metal layer; and
a second insulating layer separating the second inner plate from the second outer plate.

10. The logic cell of claim 9, wherein:
the second outer plate is directly electrically connected to the second power rail; and
the second inner plate is directly electrically connected to a second frontside via bar of the topside metal layer.

11. The logic cell of claim 10, wherein the insulating layer and the second insulating layer each include either at least one dielectric material, or multiple alternating layers of a ferroelectric material and a dielectric material stacked on top each other.

12. A logic cell comprising:
a first trench capacitor disposed between and connecting a topside metal layer to a backside metal layer, wherein the first trench capacitor comprises:
an outer plate connected to a first power rail on the backside metal layer;
an inner plate connected to a second power rail on the backside metal layer; and
an insulating layer separating the inner plate from the outer plate; and.
a metal conductor electrically connecting a second frontside via bar with the second power rail on the backside metal layer.

13. The logic cell of claim 12, wherein:
the inner plate is directly electrically connected to a first frontside via bar on the topside metal layer; and
the first frontside via bar is electrically connected to the metal conductor.

14. The logic cell of claim 13, further comprising:
a source drain contact electrically connecting the first frontside via bar to the second frontside via bar; and
a gate contact electrically connecting the outer plate of the first trench capacitor to a gate line of the logic cell.

15. The logic cell of claim 13, further comprising:
a gate line electrically connecting the first frontside via bar to the second frontside via bar; and
a source drain contact of the logic cell electrically connected to the outer plate of the first trench capacitor.

16. The logic cell of claim 15, wherein the insulating layer includes multiple alternating layers of a ferroelectric material and a dielectric material stacked on top each other.

17. A logic cell comprising:
a first trench capacitor disposed between and connecting a topside metal layer to a backside metal layer, wherein the first trench capacitor comprises:
a first outer plate directly electrically connected to a first power rail on the backside metal layer;
a first inner plate connected to a second power rail on backside metal layer; and
a first insulating layer separating the first inner plate from the first outer plate; and
a second trench capacitor disposed between and connecting the topside metal layer to the backside metal layer, wherein the second trench capacitor comprises:
a second outer plate directly electrically connected to the second power rail on the backside metal layer;
a second inner plate connected to the first power rail on backside metal layer; and
a second insulating layer separating the second inner plate from the second outer plate.

18. The logic cell of claim 17, wherein at least one of the first insulating layer or the second insulating layer includes multiple alternating layers of a ferroelectric material and a dielectric material stacked on top each other.

19. The logic cell of claim 17, further comprising:
a first frontside via bar of the topside metal layer directly electrically connected to the first inner plate;
a second frontside via bar of the topside metal layer directly electrically connected to the second inner plate;
a first set of source drain contacts of the logic cell electrically connecting the first outer plate to the second frontside via bar;
a second set of source drain contacts of the logic cell electrically connecting the second outer plate to the first frontside via bar; and
a plurality of gate contacts, each connecting a respective one of the first and second sets of source drain contacts with an adjacent gate line, wherein
the first and second sets of source drain contacts are arranged in an alternating arrangement.

20. The logic cell of claim 17, further comprising:
a first frontside via bar of the topside metal layer directly electrically connected to the first inner plate;
a second frontside via bar of the topside metal layer directly electrically connected to the second inner plate;
a first gate contact electrically connecting the first frontside via bar to a gate line;
a second gate contact electrically connecting the first gate line to the second outer plate;
a third gate contact electrically connecting the second frontside via bar to a second gate line;
a fourth gate contact electrically connecting the second gate line to the first outer plate;
a first source drain contact electrically connecting the second frontside via bar to the first outer plate; and
a second source drain contact electrically connecting the first frontside via bar to second outer plate.
